(19) United States
(12) Patent Application Publication
(10) Pub. No.: US 2024/0210473 A1
(43) Pub. Date: Jun. 27, 2024

(54) SEMICONDUCTOR CHIP AND SEMICONDUCTOR PACKAGE INCLUDING THE SAME

(71) Applicant: SAMSUNG ELECTRONICS CO., LTD., Suwon-si (KR)

(72) Inventors: Jangmok Yoo, Suwon-si (KR); Jaeyong Jeong, Suwon-si (KR)

(73) Assignee: SAMSUNG ELECTRONICS CO., LTD., Suwon-si (KR)

(21) Appl. No.: 18/532,340

(22) Filed: Dec. 7, 2023

(30) Foreign Application Priority Data
Dec. 27, 2022 (KR) 10-2022-0186037

(51) Int. Cl. G01R 31/3187; G01R 31/317; G06F 1/10

(52) U.S. Cl. CPC G01R 31/3187; G01R 31/31727; G06F 1/10

(57) ABSTRACT

A semiconductor chip includes a wiring structure arranged along an edge of the semiconductor chip; a clock counter configured to output a test signal to a first node of the wiring structure and receive the test signal from a second node of the wiring structure; and an oscillator configured to output a first clock signal to the clock counter, where the clock counter is configured to count a number of clocks of the first clock signal as a first count value from a first time in which the test signal is output to the first node of the wiring structure to a second time in which the test signal is received from the second node of the wiring structure, and output a first resultant signal to a controller based on the first count value.

### CROSS-REFERENCE TO RELATED APPLICATION

This application is based on and claims priority under 35 U.S.C. § 119 to Korean Patent Application No. 10-2022-0186037, filed on Dec. 27, 2022, in the Korean Intellectual Property Office, the disclosure of which is incorporated by reference herein in its entirety.

### BACKGROUND

The embodiments relate to a semiconductor chip and a semiconductor package including the semiconductor chip, and particularly to a semiconductor chip that may determine whether a semiconductor chip has a defect by using a clock counter and a semiconductor package including the semiconductor chip.

When dicing from a wafer to individual semiconductor chips is performed during a process of manufacturing a semiconductor package, edges of a semiconductor chip may crack. Even though an initial crack may not present problems, the crack may spread over time and reduce the quality and reliability of semiconductor chips and semiconductor packages. Accordingly, technology for detecting cracks is required to be developed.

### SUMMARY

The embodiments provide a semiconductor chip that may determine whether the semiconductor chip has a defect by using a clock counter and a semiconductor package including the semiconductor chip.

According to one or more embodiments, a semiconductor chip comprises a wiring structure arranged along an edge of the semiconductor chip; a clock counter configured to output a test signal to a first node of the wiring structure and receive the test signal from a second node of the wiring structure; and an oscillator configured to output a first clock signal to the clock counter, wherein the clock counter counts a number of clocks of the first clock signal as a first count value from a first time in which the test signal is output to the first node of the wiring structure to a second time in which the test signal is received from the second node of the wiring structure, and outputs a first resultant signal to a controller based on the first count value.

According to one or more embodiments, a semiconductor package comprises: a semiconductor chip: and a controller configured to output a test command signal to the semiconductor chip, wherein the semiconductor chip comprises: a wiring structure arranged in an edge of the semiconductor chip, a clock counter configured to output a test signal to a first node of the wiring structure in response to the test command signal received from the controller and receive the test signal from a second node of the wiring structure, and an oscillator configured to output a first clock signal to the clock counter, and wherein the clock counter counts a number of clocks of the first clock signal as a first count value from a first time in which the test signal is output to the first node of the wiring structure to a second time in which the test signal is received from the second node of the wiring structure, and outputs a first resultant signal to the controller based on the first count value.

According to one or more embodiments, a semiconductor package comprising: a plurality of semiconductor chips: and a controller configured to output a test command signal to the plurality of semiconductor chips, wherein each of the plurality of semiconductor chips comprises: a wiring structure arranged in an edge of the semiconductor chip, a clock counter configured to output a test signal to a first node of the wiring structure in response to the test command signal and receive the test signal from a second node of the wiring structure, and an oscillator configured to output a first clock signal to the clock counter, and wherein the clock counter counts a number of clocks of the first clock signal as a first count value from a first time in which the test signal is output to the first node of the wiring structure to a second time in which the test signal is received from the second node of the wiring structure, and outputs a first resultant signal to the controller based on the first count value.

### BRIEF DESCRIPTION OF DRAWINGS

Embodiments will be more clearly understood from the following detailed description taken in conjunction with the accompanying drawings in which:

FIG. 1 is a block diagram illustrating a semiconductor package according to one or more embodiments:

FIG. 2 is a block diagram illustrating a semiconductor chip according to one or more embodiments:

FIG. 3 is a flowchart illustrating an operating method of a clock counter of a semiconductor chip, according to one or more embodiments:

FIG. 4 is a flowchart illustrating a method of generating a first resultant signal by using a clock counter of a semiconductor chip, according to one or more embodiments:

FIG. 5 is a flowchart illustrating an operating method of a controller of a semiconductor package, according to one or more embodiments:

FIG. 6 is a flowchart illustrating a method of determining whether a semiconductor chip has a defect by using a controller of a semiconductor package, according to one or more embodiments:

FIG. 7 is a timing diagram illustrating an example of signals input to and output from a clock counter of a semiconductor chip, according to one or more embodiments:

FIG. 8 is a table illustrating a result of determining whether a semiconductor chip has a defect based on a resultant signal and a count value by using a controller, according to one or more embodiments:

FIG. 9 is a block diagram illustrating a semiconductor chip according to one or more embodiments:

FIG. 10 is a table illustrating a result of determining whether a semiconductor chip has a defect based on a resultant signal and a count value by using a controller, according to one or more embodiments:

FIG. 11 is a block diagram illustrating a semiconductor chip according to one or more embodiments: and

FIG. 12 is a table illustrating a result of determining whether a semiconductor chip has a defect based on a resultant signal and a count value by using a controller, according to one or more embodiments.

### DETAILED DESCRIPTION OF EMBODIMENTS

Hereinafter, embodiments are described in detail with reference to the accompanying drawings.

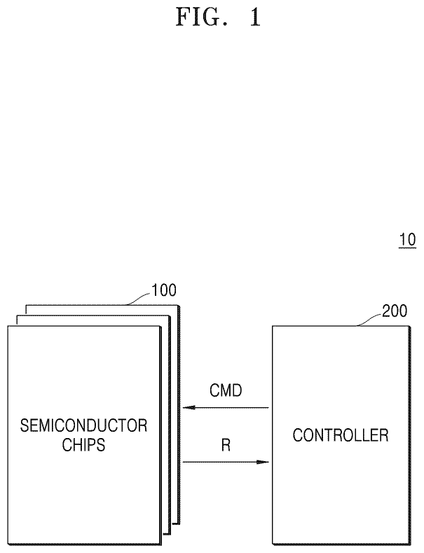

FIG. 1 is a block diagram illustrating a semiconductor package according to one or more embodiments.

Referring to FIG. 1, a semiconductor package 10 according to one or more embodiments may include a plurality of semiconductor chips 100 and a controller 200.

In one or more examples, the semiconductor package 10 may include a package substrate, where a plurality of semiconductor chips 100 and a controller 200 may be mounted on the package substrate.

Each of the plurality of semiconductor chips 100 may be obtained by dicing a wafer substrate containing the semiconductor chips into a preset size. In one or more embodiments, the plurality of semiconductor chips 100 may be obtained by being diced into a rectangular or square shape but are not limited thereto.

The one or more of the plurality of semiconductor chips 100 may develop defects, such as cracks, while being diced or assembled into the semiconductor package 10. The defects, such as cracks, may cause physical defects of internal components of the plurality of semiconductor chips 100. The defects may cause a problem in quality and reliability of the plurality of semiconductor chips 100 and the semiconductor package 10 including the semiconductor chips 100. As understood by one of ordinary skill in the art, the defects may be preexisting before the wafer is diced, or may develop as a result of the wafer being diced.

In one or more embodiments, the plurality of semiconductor chips 100 may perform self-diagnostic test operations to determine whether the plurality of semiconductor chips 100 have defects, such as cracks. In one or more examples, the plurality of semiconductor chips 100 may output resultant signals R indicating results of performing the test operations. The resultant signals R may indicate whether one or more of the plurality of semiconductor chips 100 have defects as the result of performing the test operations.

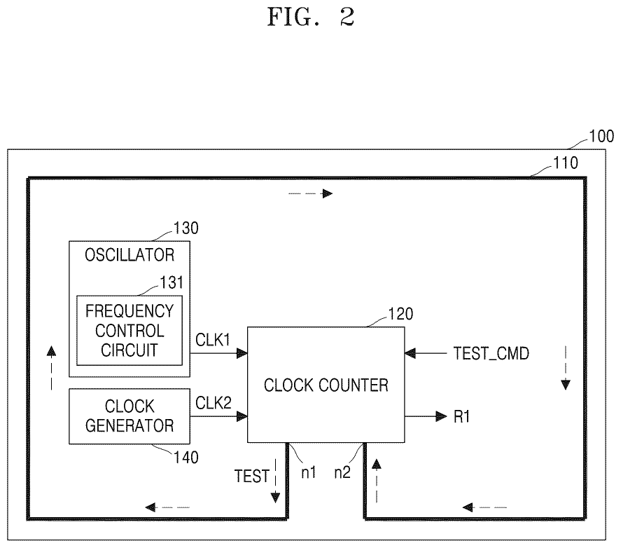

A method of performing a test operation by using the plurality of semiconductor chips 100 is described below with reference to FIG. 2.

The controller 200 may control one or more operations of the plurality of semiconductor chips 100 included in the semiconductor package 10. The controller 200 may output various types of command signals CMD to the plurality of semiconductor chips 100 included in the semiconductor package 10.

In one or more embodiments, the controller 200 may transmit test command signals to one or more of the plurality of semiconductor chips 100. The test command signals may instruct the one or more of the plurality of semiconductor chips 100 to perform a self-diagnostic test operation. The each of the semiconductor chips 100 that receive the test command signal may perform a self-diagnostic test operation in response to the test command signals received from the controller 200.

In one or more embodiments, the controller 200 may simultaneously output the test command signals to the plurality of semiconductor chips 100. Accordingly, the plurality of semiconductor chips 100 may simultaneously perform a test operation. Accordingly, the semiconductor package 10, according to one or more embodiments, may more quickly determine whether the plurality of semiconductor chips 100 have defects.

The controller 200 may receive the resultant signals R from the plurality of semiconductor chips 100. The controller 200 may determine whether the plurality of semiconductor chips 100 have defects based on the resultant signals R.

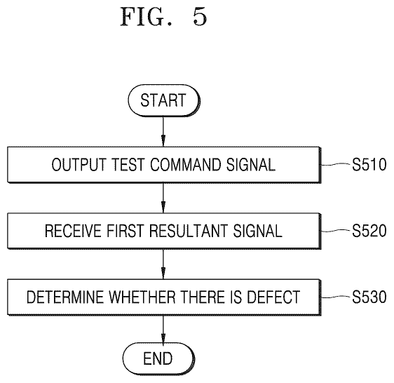

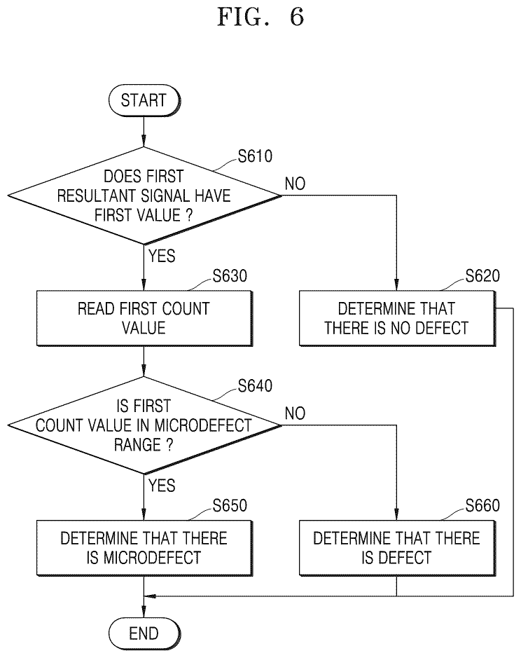

A more detailed operation of the controller 200 is described below with reference to FIGS. 5 and 6.

FIG. 2 is a block diagram illustrating a semiconductor chip according to one or more embodiments.

Referring to FIG. 2, the semiconductor chip 100, according to one or more embodiments, may include a wiring structure 110, a clock counter 120, and an oscillator 130. The semiconductor chip 100, according to one or more embodiments, may further include a clock generator 140.

The wiring structure 110 may be arranged in an edge of the semiconductor chip 100. For example, the wiring structure 110 may be separated from the edge of the semiconductor chip 100 by a preset distance. The wiring structure 110 may have the same shape as the semiconductor chip 100.

The wiring structure 110 may be connected to the clock counter 120 through a first node n1 and a second node n2.

A signal output from the clock counter 120 through the first node n1 may be input to the wiring structure 110. The signal input through the first node n1 may flow through the wiring structure 110. Because the wiring structure 110 is arranged in the edge of the semiconductor chip 100, a signal input through the first node n1 may flow through or near the edge of the semiconductor chip 100. The signal input through the first node n1 may flow in a direction indicated by a dashed arrow in FIG. 2. The signal input through the first node n1 may be output to the clock counter 120 through the second node n2. As understood by one of ordinary skill in the art, the direction of the flow illustrated in FIG. 2 may be reversed.

The signal input from the clock counter 120 through the first node n1 of the wiring structure 110 may be output to the clock counter 120 through the second node n2 of the wiring structure 110 after a preset time elapses.

In this case, when the semiconductor chip 100 has a defect, such as a crack, the wiring structure 110 may also have a physical defect. When the wiring structure 110 has a physical defect, resistance of the wiring structure 110 may increase, or the wiring structure 110 may be disconnected from the clock counter 120. In this case, a signal input to the wiring structure 110 through the first node n1 may be delayed for a preset time and output to the clock counter 120 through the second node n2 or may not be transmitted to the second node n2.

In one or more examples, the clock counter 120 may output a test signal TEST to the first node n1 of the wiring structure 110.

The test signal TEST may be a signal for determining whether the wiring structure 110 has a defect. The clock counter 120 may output the test signal TEST to the first node n1 of the wiring structure 110 in response to a test command signal TEST_CMD received from the external controller (e.g., the controller 200).

When receiving the test command signal TEST_CMD, the clock counter 120 may generate the test signal TEST. The clock counter 120 may generate the test signal TEST based on a second clock signal CLK2 received from the clock generator 140 to be described below. In addition, the clock counter 120 may output the generated test signal TEST to the first node n1 of the wiring structure 110 based on the second clock signal CLK2.

Accordingly, the test signal TEST may flow through the wiring structure 110. After the test signal TEST flows through the wiring structure 110, the test signal TEST may be input to the clock counter 120 through the second node n2 of the wiring structure 110. For example, the clock counter 120 may receive the test signal TEST from the second node n2 of the wiring structure 110.

In one or more embodiments, the clock counter 120 may count the number of clocks of a first clock signal CLK1 received from the oscillator 130 as a first count value from a first time in which the test signal TEST is output through the first node n1 of the wiring structure 110 to a second time in which the test signal TEST is received through the second node n2 of the wiring structure 110. For example, the clock counter 120 may count the number of clocks of the first clock signal CLK1 as the first count value while the test signal TEST flows through the wiring structure 110. For example, when the clock number of the first clock signal CLK1 is 5 corresponding to a first time in which the test signal TEST is input through the first node n1 of the wiring structure 110 to a second time in which the test signal TEST is output through the second node n2 of the wiring structure 110, the first count value may be 5.

In this case, the first count value may have a value corresponding to the time when the test signal TEST is transmitted through the wiring structure 110. For example, when the semiconductor chip 100 has no defect, the test signal TEST output through the first node n1 may be input through the second node n2 of the wiring structure 110 after a predetermined amount of time elapses without delay, and accordingly, the first count value may correspond to the predetermined amount of time. However, when the semiconductor chip 100 has a defect, the test signal TEST output through the first node n1 is input through the second node n2 with delay for a preset time, and accordingly, the first count value may have a greater value than the count value when the semiconductor chip 100 has the defect. For example, when the count value is 5, and the test signal is received at the second node n2 after 7 clock cycles, the semiconductor chip 100 may be determined to have a defect.

The clock counter 120 may output a first resultant signal R1 to the controller 200 based on the first count value.

The first resultant signal R1 may indicate whether the semiconductor chip 100 has a defect. The first resultant signal R1 may have one of a first value (e.g., logic 1) and a second value (e.g., logic 0). In this case, the first resultant signal R1 having the first value may indicate that the semiconductor chip 100 has a defect. However, the first resultant signal R1 having the second value may indicate that the semiconductor chip 100 has no defect.

The clock counter 120 may output the first resultant signal R1 having the first value to the controller 200 when a first count value is greater than or equal to a first reference value.

In one or more examples, the first reference value may be a reference value for determining whether the test signal TEST output through the first node n1 is input through the second node n2 with delay. The first reference value may be set slightly greater (e.g., 5% 10%) than the first count value counted by the clock counter 120 when the semiconductor chip 100 has no defect. For example, in a state where the semiconductor chip 100 has no defect, when the first count value counted by the clock counter 120 is 5, the first reference value may be set to 6 or 7.

Therefore, when the first count value is greater than or equal to the first reference value, it may be determined that the test signal TEST output through the first node n1 is input through the second node n2 with delay, and accordingly, the clock counter 120 may output the first resultant signal R1 having a first value to the controller 200.

In one or more examples, when the first count value is less than the first reference value, the clock counter 120 may output the first resultant signal R1 having a second value to the controller 200. For example, when the first count value is less than the first reference value, it may be determined that the test signal TEST output through the first node n1 is input through the second node n2 without delay, and accordingly, the clock counter 120 may output the first resultant signal R1 having the second value to the controller 200.

The oscillator 130 may generate the first clock signal CLK1. The oscillator 130 may output the first clock signal CLK1 to the clock counter 120.

The oscillator 130 may include a frequency control circuit 131. The frequency control circuit 131 may adjust a frequency of the first clock signal CLK1. For example, the frequency control circuit 131 may increase the frequency of the first clock signal CLK1. Accordingly, even when a size of the semiconductor chip 100 is small, it is possible to more accurately determine whether the semiconductor chip 100 has a defect. The frequency of the clock signal may vary based on a size of the semiconductor chip 100, thereby increasing the accuracy of determining whether the semiconductor chip 100 includes a defect.

The clock generator 140 may output a second clock signal CLK2 to the clock counter 120. The clock generator 140 may generate the second clock signal CLK2 based on the first clock signal CLK1 generated by the oscillator 130, where the second clock signal CLK2 may have a lower frequency than the first clock signal CLK1. However, as understood by one of ordinary skill in the art, the second clock signal CLK2 may have a higher frequency than the first clock signal CLK1.

As described above, according to the semiconductor chip 100 of one or more embodiments and the semiconductor package 10 including the semiconductor chip 100, the clock counter 120 may count the number of clocks from a point in time (e.g., first point in time) when the test signal TEST is output to a point in time (e.g., second point in time) when the test signal TEST is input, and subsequently output the first resultant signal R1 indicating whether a semiconductor chip has a defect. As a result of these features, the quality and reliability of the semiconductor chip 100 and the semiconductor package 10 may be increased.

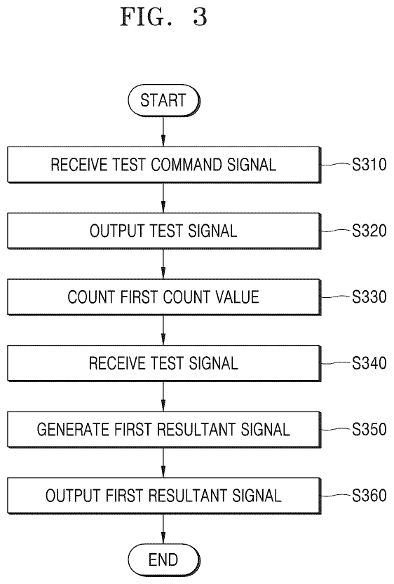

FIG. 3 is a flowchart illustrating an operating method of a clock counter of a semiconductor chip, according to one or more embodiments.

Referring to FIG. 3, in operation S310, the clock counter 120 may receive the test command signal TEST_CMD. When receiving the test command signal TEST_CMD from the controller 200, the clock counter 120 may perform a test operation of determining whether the semiconductor chip 100 has a defect such as a crack.

In operation S320, the clock counter 120 may output the test signal TEST. The clock counter 120 may generate the test signal TEST based on the second clock signal CLK2 received from the clock generator 140 and output the test signal TEST to the first node n1 of the wiring structure 110.

In operation S330, the clock counter 120 may count a first count value. The clock counter 120 may output the test signal TEST to the first node n1 of the wiring structure 110 and subsequently count the number of clocks of the first clock signal CLK1 as the first count value. For example, the clock counter 120 may count the number of rising edges or the number of falling edges of the first clock signal CLK1 to obtain the first count value.

In operation S340, the clock counter 120 may receive the test signal TEST. The clock counter 120 may receive the test signal TEST flowing through the wiring structure 110 at the second node n2 of the wiring structure 110. The clock counter 120 may continue counting the first count value until receiving the test signal TEST through the second node n2.

When the semiconductor chip 100 has a defect, such as disconnection of the wiring structure 110, the clock counter 120 may not receive the test signal TEST at the second node n2 of the wiring structure 110. In this case, the clock counter 120 may continuously count the first count value. In one or more examples, if the test signal TEST is not received at the second node n2, the clock counter 120 may stop counting the first count value after the first count value reaches a maximum count (e.g., 100 clock cycles).

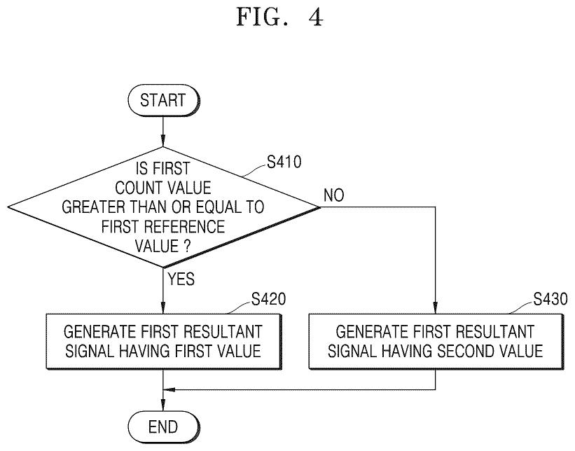

In operation S350, the clock counter 120 may generate the first resultant signal R1. The clock counter 120 may generate the first resultant signal R1 based on the first count value, which is described in more detail with reference to FIG. 4.

FIG. 4 is a flowchart illustrating a method of generating a first resultant signal by using a clock counter of a semiconductor chip, according to one or more embodiments.

Referring to FIG. 4, in operation S410, the clock counter 120 may determine whether the first count value is greater than or equal to a first reference value. When the first count value is greater than or equal to the first reference value, it may be determined that the semiconductor chip 100 has a defect. However, when the first count value is less than the first reference value, it may be determined that the semiconductor chip 100 does not have a defect.

When it is determined that the first count value is greater than or equal to the first reference value, the process proceeds to operation S420, and the clock counter 120 may generate the first resultant signal R1 having a first value. In this case, the first value may indicate that the semiconductor chip 100 has a defect and may be set to, for example, logic 1.

When it is determined that the first count value is less than the first reference value, the process proceeds to operation S430, and the clock counter 120 may generate the first resultant signal R1 having a second value. In this case, the second value may indicate that the semiconductor chip 100 has no defect and may be set to, for example, logic 0.

Referring again to FIG. 3, when receiving the test signal TEST through the second node n2 of the wiring structure 110 as in operation S340, the clock counter 120 may generate the first resultant signal R1 in operation S350. However, when the semiconductor chip 100 has a defect, such as disconnection of the wiring structure 110, the clock counter 120 may not receive the test signal TEST through the second node n2 of the wiring structure 110. In this case, even when the clock counter 120 does not receive the test signal TEST through the second node n2 of the wiring structure 110 as in operation S340, when the first count value is much greater than the first reference value (e.g., when the first count value is double or more than the first reference value), the clock counter 120 may generate the first resultant signal R1 as in operation S350.

In operation S360, the clock counter 120 may output the first resultant signal R1. The clock counter 120 may inform the controller 200 of whether the semiconductor chip 100 has a defect by outputting the first resultant signal R1 to the controller 200.

FIG. 5 is a flowchart illustrating an operating method of a controller of a semiconductor package, according to one or more embodiments.

Referring to FIG. 5, in operation S510, the controller 200 may output the test command signal TEST_CMD. The controller 200 may output the test command signal TEST_CMD to the clock counter 120 of the semiconductor chip 100 to check whether the semiconductor chip 100 has a defect. In one or more embodiments, when a plurality of semiconductor chips 100 are included in the semiconductor package 10, the controller 200 may simultaneously output the test command signal TEST_CMD to the plurality of semiconductor chips 100. In one or more examples, the test command signal may be output by the controller 200 to each semiconductor chip 100 periodically. In one or more examples, the test command signal may be output by the controller 200 when a condition is satisfied (e.g., semiconductor chip is in use for a predetermined period of time).

In operation S520, the controller 200 may receive the first resultant signal R1. The controller 200 may output the test command signal TEST_CMD and then receive the first resultant signal R1 from the clock counter 120 after the time required for the clock counter 120 to perform the test elapsed.

In operation S530, the controller 200 may determine whether the semiconductor chip 100 has a defect. The controller 200 may determine whether the semiconductor chip 100 has a defect based on the first resultant signal R1 received in operation S520. This is described in more detail with reference to FIG. 6.

FIG. 6 is a flowchart illustrating a method of determining whether a semiconductor chip has a defect by using a controller of a semiconductor package, according to one or more embodiments.

Referring to FIG. 6, in operation S610, the controller 200 may determine whether the first resultant signal R1 has a first value (e.g., logic 1 or logic high). The controller 200 may determine whether the semiconductor chip 100 has a defect by determining whether the first resultant signal R1 has the first value.

When it is determined that the first resultant signal R1 does not have the first value, the controller 200 may determine that the semiconductor chip 100 has no defect in operation S620.

When it is determined that the first resultant signal R1 has the first value, the controller 200 may read the first count value in operation S630. For example, when it is determined that the semiconductor chip 100 has a defect, the controller 200 may read the first count value counted by the clock counter 120. The controller 200 may determine a defect level of the semiconductor chip 100 based on the first count value. For example, the defect level may be correlated with an amount of delay of a signal propagating through a wiring structure of a semiconductor chip (e.g., larger delay may indicate larger defect).

In operation S640, the controller 200 may determine whether the first count value is in a microdefect range. In one or more examples, the microdefect may refer to a defect of the semiconductor chip 100 that is difficult to be checked through an X-ray. In this case, the microdefect range may be a range of a reference for determining that the defect of the semiconductor chip 100 is a microdefect. In one or more embodiments, the microdefect range may refer to a range in which the first count value exceeds the first reference value within a preset ratio (for example, 60%). For example, when the first reference value is 10, the microdefect range may be set to a range of about 10 to about 16.

When the first count value is in the microdefect range, the controller 200 may determine that the semiconductor chip 100 has a microdefect in operation S650.

When the first count value is not in the microdefect range, the controller 200 may determine that the semiconductor chip 100 has a defect in operation S660. For example, when the first count value is not in the microdefect range, the controller 200 may determine the defect of the semiconductor chip 100 as another defect other than the microdefect.

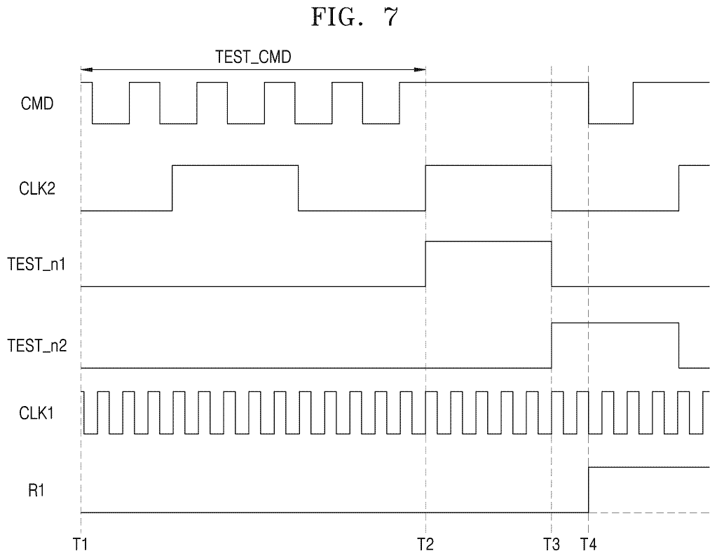

FIG. 7 is a timing diagram illustrating an example of signals input to and output from and to a clock counter of a semiconductor chip according to one or more embodiments.

Referring to FIG. 7, the example shows a signal flow of the command signal CMD, the first clock signal CLK1, the second clock signal CLK2, and a second test signal TEST_n2, which are signals input to the clock counter 120, and a signal flow of a first test signal TEST_n1 and the first resultant signal R1 which are signals output from the clock counter 120. In one or more examples, the first test signal TEST_n1 may indicate the test signal TEST measured at the first node n1, and the second test signal TEST_n2 may indicate the test signal TEST measured at the second node n2.

In the embodiment of FIG. 7, the first clock signal CLK1 and the second clock signal CLK2 may be continuously input from the oscillator 130 and the clock generator 140, respectively.

In one or more examples, the test command signal TEST_CMD is input as the command signal CMD from the first point in time T1 to the second point in time T2. Values of the first test signal TEST_n1, the second test signal TEST_n2, and the first resultant signal R1 from the first point in time T1 to the second point in time T2 may be logic 0.

At the second point in time T2, input of the test command signals TEST_CMD is completed, and the clock counter 120 may generate and output the first test signal TEST_n1 based on the second clock signal CLK2. The clock counter 120 may generate the second clock signal CLK2 of one cycle having the same rising edge and falling edge as the second clock signal CLK2 as the first test signal TEST_n1, and output the second clock signal CLK2 to the wiring structure 110.

In this case, the clock counter 120 may count the number of clocks of the first clock signal CLK1 as a first count value from the second point in time T2 when the first test signal TEST_n1 is output.

At a third point in time T3, the second test signal TEST_n2 may be input from the wiring structure 110 to the clock counter 120. In this case, the clock counter 120 may count the first count value until the third point in time T3 when the second test signal TEST_n2 is input. For example, the clock counter 120 may count the number of clocks of the first clock signal CLK1 from the second point in time T2 to the third point in time T3 as the first count value. In the embodiment of FIG. 7, the first count value may be 5.

The clock counter 120 may set the first resultant signal R1 based on a result of comparing the first count value with the first reference value and output the first resultant signal R1 from a fourth point in time T4. In the embodiment of FIG. 7, when the first reference value is less than 5, a value of the first resultant signal R1 may be logic 1 as illustrated by the solid line. In contrast to this, and when the first reference value is 5 or more, the value of the first resultant signal R1 may be logic 0 as illustrated by the dashed line.

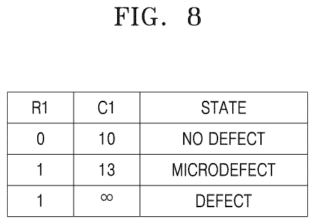

FIG. 8 is a table illustrating a result that a controller according to one or more embodiments determines whether a semiconductor chip has a defect based on a resultant signal and a count value.

Referring to FIG. 8, the table shows a result that the controller 200 determines a state of the semiconductor chip 100 based on the first resultant signal R1 and a first count value C1. In the embodiment of FIG. 8, the first reference value is 11, and a microdefect range may be about 11 to about 16.

When a value of the first resultant signal R1 is logic 0, the controller 200 may determine that the semiconductor chip 100 has no defect regardless of the first count value C1.

When the value of the first resultant signal R1 is logic 1 and the first count value C1 is 13, the controller 200 may determine that the semiconductor chip 100 has a microdefect.

When the value of the first resultant signal R1 is logic 1 and the first count value C1 is x, the controller 200 may determine that the semiconductor chip 100 has a defect.

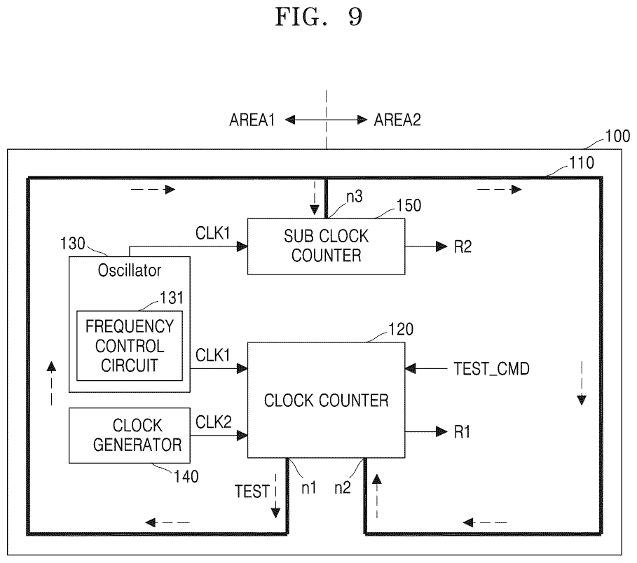

FIG. 9 is a block diagram illustrating a semiconductor chip according to one or more embodiments.

Referring to FIG. 9, a semiconductor chip 100 according to one or more embodiments may include a wiring structure 110, a clock counter 120, and an oscillator 130. The semiconductor chip 100 according to the embodiment may further include a clock generator 140. The semiconductor chip 100, according to one or more embodiments, may further include a sub clock counter 150. The wiring structure 110, the clock counter 120, the oscillator 130, and the clock generator 140 included in the semiconductor chip 100, according to one or more embodiments, may perform the same operations as described above with reference to FIG. 2.

The sub clock counter 150 may count the number of clocks of a first clock signal CLK1 received from the oscillator 130 as a second count value from when a test signal TEST is input to a first node n1 of the wiring structure 110 by the clock counter 120 to when the test signal TEST is received from a third node n3 of the wiring structure 110.

In this case, in the embodiment of FIG. 9, the third node n3 of the wiring structure 110 may be between the first node n1 and a second node n2 of the wiring structure 110. For example, the sub clock counter 150 may count the number of clocks of a first clock signal CLK1 as a second count value while the test signal TEST flows to the middle of the wiring structure 110. For example, when the number of clocks of the first clock signal CLK1 is 3 from a first time in which the test signal TEST is input through the first node n1 of the wiring structure 110 to a second time in which the test signal TEST is output through the third node n3 of the wiring structure 110, the second count value may be 3.

The sub clock counter 150 may output a second resultant signal R2 to the controller 200 based on the second count value.

The second resultant signal R2 may indicate whether there is a defect in a first area AREA1 corresponding to the first node n1 to the third node n3 of the wiring structure 110 of the semiconductor chip 100. In the example of FIG. 9, the first area AREA1 may be the left area of the semiconductor chip 100.

The second resultant signal R2 may have one of a first value and a second value. In this case, when the second resultant signal R2 has the first value, it may be determined that the first area AREA1 of the semiconductor chip 100 has a defect. When the second resultant signal R2 has the second value, it may be determined that the first area AREA1 of the semiconductor chip 100 has no defect.

The sub clock counter 150 may output the second resultant signal R2 having the first value to the controller 200 when the second count value is greater than or equal to a second reference value.

In one or more examples, the second reference value may be a reference value for determining whether the test signal TEST output through the first node n1 is input through the third node n3 with delay. The second reference value may be set to be slightly greater than the second count value counted by the sub clock counter 150 when the first area AREA1 of the semiconductor chip 100 has no defect. For example, when the first area AREA1 of the semiconductor chip 100 has no defect and the second count value counted by the sub clock counter 150 is 3, the second reference value may be set to 4 or 5.

Therefore, when the second count value is greater than or equal to the second reference value, it may be determined that the test signal TEST output through the first node n1 is input through the third node n3 with delay, and accordingly, the sub clock counter 150 may output the second resultant signal R2 having the first value to the controller 200.

In one or more examples, when the second count value is less than the second reference value, the sub clock counter 150 may output the second resultant signal R2 having the second value to the controller 200. For example, when the second count value is less than the second reference value, may be determined that the test signal TEST output through the first node n1 is input through the third node n3 without delay, the sub clock counter 150 may output the second resultant signal R2 having the second value to the controller 200.

The controller 200 may determine whether the semiconductor chip 100 has a defect and a defective area based on the first resultant signal R1 received from the clock counter 120 and the second resultant signal R2 received from the sub clock counter 150.

In one or more examples, when the first resultant signal R1 has the first value and the second resultant signal R2 has the first value, the controller 200 may determine that the first area AREA of the semiconductor chip 100 has a defect. In one or more examples, when the first resultant signal R1 has the first value and the second resultant signal R2 has the second value, the controller 200 may determine that the second area AREA2 of the semiconductor chip 100 has a defect. In one or more examples, when the first resultant signal R1 has the second value and the second resultant signal R2 has the second value, the controller 200 may determine that the semiconductor chip 100 has no defect.

When it is determined that the semiconductor chip 100 has a defect, the controller 200 may read the first count value counted by the clock counter 120 and the second count value counted by the sub clock counter 150. Furthermore, the controller 200 may determine a defect level of the semiconductor chip 100 based on the first count value and the second count value. For example, the controller 200 may determine the defect level of the semiconductor chip by determining whether the first count value is in a first microdefect range (e.g., microdefect in the first area AREA1) and the second count value is in a second microdefect range (e.g., microdefect in the second area AREA2).

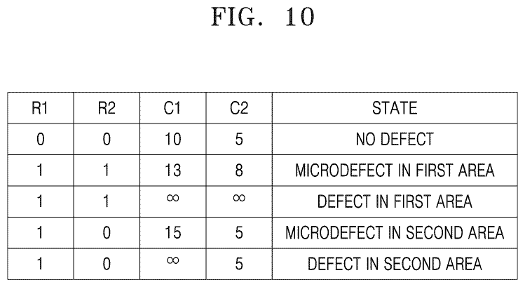

FIG. 10 is a table illustrating a result that a controller according to one or more embodiments determines whether a semiconductor chip has a defect, based on a resultant signal and a count value.

Referring to FIG. 10, the table shows a result that the controller 200 determines a state of the semiconductor chip 100 based on the first resultant signal R1, the second resultant signal R2, the first count value C1, and the second count value C2. In the embodiment of FIG. 10, a first reference value may be 11, a second reference value may be 6, a first microdefect range may be 11 to 16, and a second microdefect range may be about 6 to about 8.

In one or more examples, when a value of the first resultant signal R1 and a value of the second resultant signal R2 are logic 0, the controller 200 may determine that the semiconductor chip 100 has no defect regardless of the first count value C1 and the second count value C2.

In one or more examples, when the value of the first resultant signal R1 and the value of the second resultant signal R2 are logic 1, the first count value C1 is 13, and the second count value C2 is 8, the controller 200 may determine that the first area AREA1 of the semiconductor chip 100 has a microdefect.

In one or more examples, when the value of the first resultant signal R1 and the value of the second resultant signal R2 are logic 1, the first count value C1 is x, and the second count value C2 is x, the controller 200 may determine that the first area AREA1 of the semiconductor chip 100 has a defect. In one or more examples, a count value may be determined as x when the count value exceeds a maximum threshold.

In one or more examples, when the value of the first resultant signal R1 is logic 1, the value of the second resultant signal R2 is logic 0, the first count value C1 is 15, and the second count value C2 is 5, the controller 200 may determine that the second area AREA2 of the semiconductor chip 100 has a microdefect.

In one or more examples, when the value of the first resultant signal R1 is logic 1, the value of the second resultant signal R2 is logic 0, the first count value C1 is x, and the second count value C2 is 5, the controller 200 may determine that the second area AREA2 of the semiconductor chip 100 has a defect.

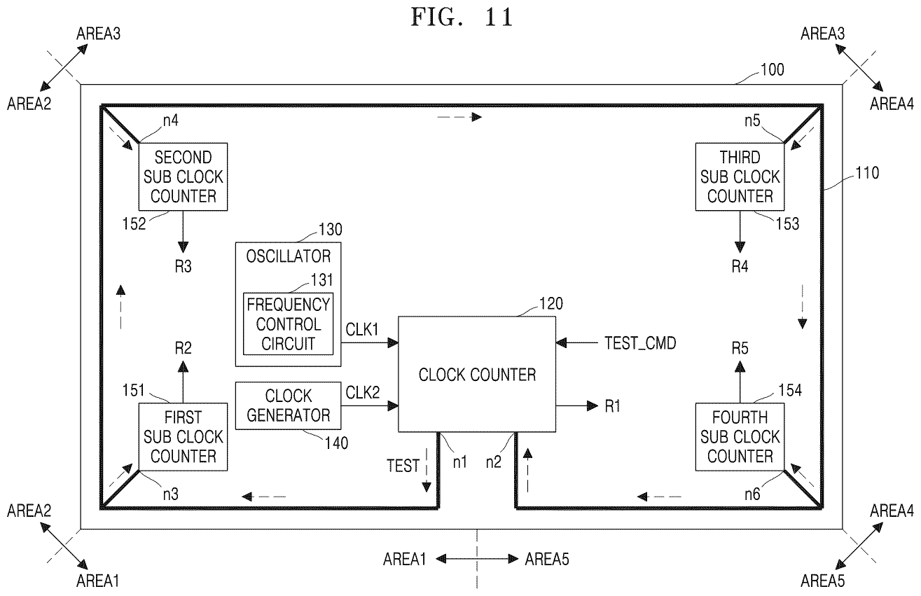

FIG. 11 is a block diagram illustrating a semiconductor chip according to one or more embodiments.

Referring to FIG. 11, a semiconductor chip 100, according to one or more embodiments, may include a wiring structure 110, a clock counter 120, and an oscillator 130. The semiconductor chip 100, according to one or more embodiments, may further include a clock generator 140. In addition, the semiconductor chip 100, according to one or more embodiments, may further include a first sub clock counter 151, a second sub clock counter 152, a third sub clock counter 153, and a fourth sub clock counter 154. The wiring structure 110, the clock counter 120, the oscillator 130, and the clock generator 140 included in the semiconductor chip 100, according to one or more embodiments, may perform the same operations as described above with reference to FIG. 2.

The first sub clock counter 151 may count the number of clocks of a first clock signal CLK1 received from the oscillator 130 as a second count value from a first time point in which the test signal TEST is input to a first node n1 of the wiring structure 110 by the clock counter 120 to a second time point in which the test signal TEST is received from a third node n3 of the wiring structure 110.

The second sub clock counter 152 may count the number of clocks of the first clock signal CLK1 received from the oscillator 130 as a third count value from a first time point in which the test signal TEST is input to the first node n1 of the wiring structure 110 by the clock counter 120 to a second time point in which the test signal TEST is received from a fourth node n4 of the wiring structure 110.

The third sub clock counter 153 may count the number of clocks of the first clock signal CLK1 received from the oscillator 130 as a fourth count value from a first time point in which the test signal TEST is input to the first node n1 of the wiring structure 110 by the clock counter 120 to a second time point in which the test signal TEST is received from a fifth node n5 of the wiring structure 110.

The fourth sub clock counter 154 may count the number of clocks of the first clock signal CLK1 received from the oscillator 130 as a fifth count value from a first time point in which the test signal TEST is input to the first node n1 of the wiring structure 110 by the clock counter 120 to a second time point in which the test signal TEST is received from a sixth node n6 of the wiring structure 110.

In this case, in the embodiment of FIG. 11, the third node n3, the fourth node n4, the fifth node n5, and the sixth node n6 of the wiring structure 110 may be in respective corners of the wiring structure 110. For example, while the test signal TEST flows to the respective corners of the wiring structure 110, the first to fourth sub clock counters 151 to 154 may count the number of clocks of the first clock signal CLK1 as the second to fifth count values.

The first sub clock counter 151 may output a second resultant signal R2 to the controller 200 based on the second count value. The second resultant signal R2 may indicate whether there is a defect in a first area AREA1 corresponding to the first node n1 to the third node n3 of the wiring structure 110 of the semiconductor chip 100. In the example of FIG. 11, the first area AREA1 may be the lower left area of the semiconductor chip 100.

The second resultant signal R2 may have one of a first value and a second value. In this case, when the second resultant signal R2 has the first value, it may be determined that the first area AREA1 of the semiconductor chip 100 has a defect. When the second resultant signal R2 has the second value, it may be determined that that the first area AREA1 of the semiconductor chip 100 has no defect.

When the second count value is greater than or equal to a second reference value, the first sub clock counter 151 may output the second resultant signal R2 having the first value to the controller 200.

In one or more examples, the second reference value may be a reference value for determining whether the test signal TEST output through the first node n1 is input through the third node n3 with delay. Therefore, when the second count value is greater than or equal to the second reference value, it may be determined that the test signal TEST output through the first node n1 is input through the third node n3 with delay, and accordingly, the first sub clock counter 151 may output the second resultant signal R2 having the first value to the controller 200. When the second count value is less than the second reference value, the first sub clock counter 151 may output a second resultant signal R2 having the second value to the controller 200.

The second sub clock counter 152 may output a third resultant signal R3 to the controller 200 based on the third count value. The third resultant signal R3 may indicate whether there are defects in the first area AREA1 and the second area AREA2 corresponding to the first node n1 to the fourth node n4 of the wiring structure 110 of the semiconductor chip 100. In the embodiment of FIG. 11, the second area AREA2 may be the left area of the semiconductor chip 100.

The third resultant signal R3 may have one of a first value and a second value. In this case, when the third resultant signal R3 has the first value, it may be determined that there are defects in the first area AREA1 and the second area AREA2 of the semiconductor chip 100. When the second resultant signal R2 has the second value, it may be determined that there are no defects in the first area AREA1 and the second area AREA2 of the semiconductor chip 100.

In one or more examples, a third reference value may be a reference value for determining whether the test signal TEST output through the first node n1 is input through the fourth node n4 with delay. Therefore, when the third count value is greater than or equal to the third reference value, it may be determined that the test signal TEST output through the first node n1 is input through the fourth node n4 with delay, and accordingly, the second sub clock counter 152 may output the third resultant signal R3 having the first value to the controller 200. When the third count value is less than the third reference value, the second sub clock counter 152 may output a third resultant signal R3 having the second value to the controller 200.

The third sub clock counter 153 may output a fourth resultant signal R4 to the controller 200 based on the fourth count value. The fourth resultant signal R4 may indicate whether there are defects in the first are AREA1 to the third area AREA3 corresponding to the first node n1 to the fifth node n5 of the wiring structure 110 of the semiconductor chip 100. In the embodiment of FIG. 11, the third area AREA3 may be the upper area of the semiconductor chip 100.

A fourth resultant signal R4 may have one of a first value and a second value. In this case, when the fourth resultant signal R4 has the first value, may be determined that the first area AREA1 to the third area AREA3 of the semiconductor chip 100 have defects. When the fourth resultant signal R4 has the second value, it may be determined that the first area AREA1 to the third area AREA3 of the semiconductor chip 100 have no defect.

In one or more examples, a fourth reference value may be a reference value for determining whether the test signal TEST output through the first node n1 is input through the fifth node n5 with delay. Therefore, when the fourth count value is greater than or equal to the fourth reference value, it may be determined that the test signal TEST output through the first node n1 is input through the fifth node n5 with delay, and accordingly, the third sub clock counter 153 may output the fourth resultant signal R4 having the first value to the controller 200. When the fourth count value is less than the fourth reference value, the third sub clock counter 153 may output the fourth resultant signal R4 having the second value to the controller 200.

The fourth sub clock counter 154 may output a fifth resultant signal R5 to the controller 200 based on the fifth count value. The fifth resultant signal R5 may indicate whether there are defects in the first area AREAL to the fourth area AREA4 corresponding to the first node n1 to the sixth node n6 of the wiring structure 110 of the semiconductor chip 100. In the embodiment of FIG. 11, the fourth area AREA4 may be the right area of the semiconductor chip 100.

A fifth resultant signal R5 may have any one of a first value and a second value. In this case, when the fifth resultant signal R5 has the first value, may be determined that the first area AREA1 to the fourth area AREA4 of the semiconductor chip 100 have defects. When the fifth resultant signal R5 has the second value, this may indicate that the first area AREA1 to the fourth areaAREA4 of the semiconductor chip 100 have no defect.

In one or more examples, a fifth reference value may be a reference value for determining whether the test signal TEST output through the first node n1 is input through the sixth node n6 with delay. Therefore, when the fifth count value is greater than or equal to the fifth reference value, it may be determined that the test signal TEST output through the first node n1 is input through the sixth node n6 with delay, and accordingly, the fourth sub clock counter 154 may output the fifth resultant signal R5 having the first value to the controller 200. When the fifth count value is less than the fifth reference value, the fourth sub clock counter 154 may output the fifth resultant signal R5 having the second value to the controller 200.

The controller 200 may determine whether the semiconductor chip 100 has a defect and a defective area based on the first resultant signal R1 received from the clock counter 120 and the second to fifth resultant signal R2 to R5 received from the first to fifth sub clock counters 150 to 154.

In one or more examples, when the first resultant signal R1 to the fifth resultant signal R5 each have the first value, the controller 200 may determine that the first area AREA1 of the semiconductor chip 100 has a defect.

In one or more examples, when the first resultant signal R1 has the first value, the second resultant signal R2 has the second value, and the third resultant signal R3 to the fifth resultant signal R5 each have the first value, the controller 200 may determine that the second area AREA2 of the semiconductor chip 100 has a defect.

In one or more examples, when the first resultant signal R1 has the first value, the second resultant signal R2 to the third resultant signal R3 each have the second value, and the fourth resultant signal R4 to the fifth resultant signal R5 each have the first value, the controller 200 may determine that the third area AREA3 of the semiconductor chip 100 has a defect.

In one or more examples, when the first resultant signal R1 has the first value, the second resultant signal R2 to the fourth resultant signal R4 each have the second value, and the fifth resultant signal R5 has the first value, the controller 200 may determine that the fourth area AREA4 of the semiconductor chip 100 has a defect.

In one or more examples, when the first resultant signal R1 has the first value and the second resultant signal R2 to the fifth resultant signal R5 each have the second value, the controller 200 may determine that the fifth area AREA5 of the semiconductor chip 100 has a defect. In the embodiment of FIG. 11, the fifth area AREA5 may be the lower right area of the semiconductor chip 100.

In one or more examples, when the first resultant signal R1 to the fifth resultant signal R5 each have the second value, the controller 200 may determine that the semiconductor chip 100 has no defect.

In one or more examples, when it is determined that the semiconductor chip 100 has a defect, the controller 200 may read the first count value counted by the clock counter 120 and the second count value to the fifth count value respectively counted by the first sub clock counter 151 to the fourth sub clock counter 154. In addition, the controller 200 may determine a defect level of the semiconductor chip 100 based on the first count value to the fifth count value. For example, the controller 200 may determine the defect level of the semiconductor chip by determining whether the first count value to the fifth count value are in a first microdefect range to the fifth microdefect range.

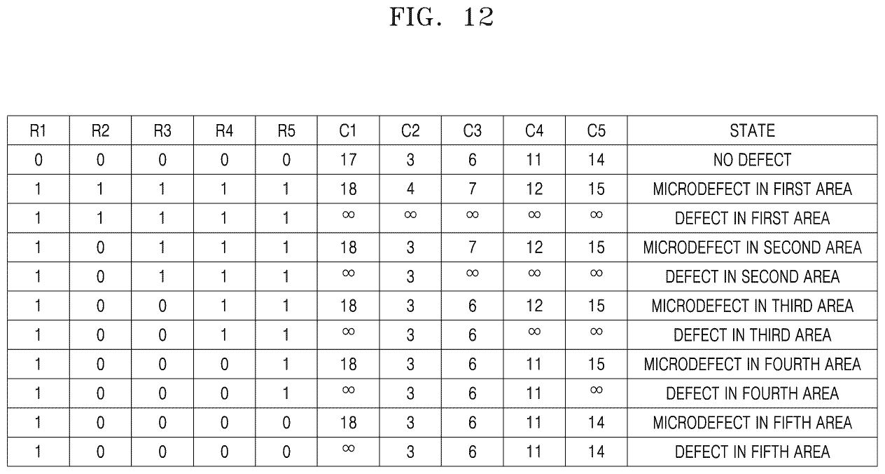

FIG. 12 is a table illustrating a result that a controller according to one or more embodiments determines whether a semiconductor chip has a defect, based on a resultant signal and a count value.

Referring to FIG. 12, the table shows a result that the controller 200 determines a state of the semiconductor chip 100 based on the first resultant signal R1 to the fifth resultant signal R5 and the first count value C1 to the fifth count value C5. In the embodiment of FIG. 12, a first reference value may be 18, a second reference value may be 4, a third reference value may be 7, a fourth reference value may be 12, and a fifth reference value may be 15.

In one or more examples, when values of the first resultant signal R1 to the fifth resultant signal R5 are logic 0, the controller 200 may determine that the semiconductor chip 100 has no defect regardless of the first count value C1 to the fifth count value C5.

In one or more examples, when the values of the first resultant signal R1 to the fifth resultant signal R5 are logic 1, the first count value C1 is 18, the second count value C2 is 4, the third count value C3 is 7, the fourth count value C4 is 12, and the fifth count value C5 is 15, the controller 200 may determine that the first area AREAL of the semiconductor chip 100 has a microdefect.

In one or more examples, when the values of the first resultant signal R1 to the fifth resultant signal R5 are logic 1, the first count value C1 is x, the second count value C2 is x, the third count value C3 is x, the fourth count value C4 is x, and the fifth count value C5 is x, the controller 200 may determine that the first area AREA1 of the semiconductor chip 100 has a defect.

In one or more examples, when the value of the first resultant signal R1 is logic 1, the value of the second resultant signal R2 is logic 0, the values of the third resultant signal R3 to the fifth resultant signal R5 are logic 1, the first count value C1 is 18, the second count value C2 is 3, the third count value C3 is 7, the fourth count value C4 is 12, and the fifth count value C5 is 15, the controller 200 may determine that the second area AREA2 of the semiconductor chip 100 has a microdefect.

In one or more examples, when the value of the first resultant signal R1 is logic 1, the value of the second resultant signal R2 is logic 0, the values of the third resultant signal R3 to the fifth resultant signal R5 are logic 1, the first count value C1 is x, the second count value C2 is 3, the third count value C3 is x, the fourth count value C4 is x, and the fifth count value C5 is x, the controller 200 may determine that the second area AREA2 of the semiconductor chip 100 has a defect.

In one or more examples, when the value of the first resultant signal R1 is logic 1, the values of the second resultant signal R2 and the third resultant signal R3 are logic 0, the values of the fourth resultant signal R4 and the fifth resultant signal R5 are logic 1, the first count value C1 is 18, the second count value C2 is 3, the third count value C3 is 6, the fourth count value C4 is 12, and the fifth count value C5 is 15, the controller 200 may determine that the third area AREA3 of the semiconductor chip 100 has a microdefect

In one or more examples, when the value of the first resultant signal R1 is logic 1, the values of the second resultant signal R2 and the third resultant signal R3 are logic 0, the values of the fourth resultant signal R4 and the fifth resultant signal R5 are logic 1, the first count value C1 is x, the second count value C2 is 3, the third count value C3 is 6, the fourth count value C4 is x, and the fifth count value C5 is x, the controller 200 may determine that the third area AREA3 of the semiconductor chip 100 has a defect.

In one or more examples, when the value of the first resultant signal R1 is logic 1, the values of the second resultant signal R2 to the fourth resultant signal R4 are logic 0, the value of the fifth resultant signal R5 is logic 1, the first count value C1 is 18, the second count value C2 is 3, the third count value C3 is 6, the fourth count value C4 is 11, and the fifth count value C5 is 15, the controller 200 may determine that the fourth area AREA4 of the semiconductor chip 100 has a microdefect.

In one or more examples, when the value of the first resultant signal R1 is logic 1, the values of the second resultant signal R2 to the fourth resultant signal R4 are logic 0, the value of the fifth resultant signal R5 is logic 1, the first count value C1 is x, the second count value C2 is 3, the third count value C3 is 6, the fourth count value C4 is 11, and the fifth count value C5 is x, the controller 200 may determine that the fourth area AREA4 of the semiconductor chip 100 has a defect.

In one or more examples, when the value of the first resultant signal R1 is logic 1, the values of the second resultant signal R2 to the fifth resultant signal R5 are logic 0, the first count value C1 is 18, the second count value C2 is 3, the third count value C3 is 6, the fourth count value C4 is 11, and the fifth count value C5 is 14, the controller 200 may determine that the fifth area AREA5 of the semiconductor chip 100 has a microdefect.

In one or more examples, when the value of the first resultant signal R1 is logic 1, the values of the second resultant signal R2 to the fifth resultant signal R5 are logic 0, the first count value C1 is x, the second count value C2 is 3, the third count value C3 is 6, the fourth count value C4 is 11, and the fifth count value C5 is 14, the controller 200 may determine that the fifth area AREA5 of the semiconductor chip 100 has a defect.

As described above, according to the semiconductor chip 100 of one or more embodiments and the semiconductor package 10 including the semiconductor chip 100, the clock counter 120 may count the number of clocks from a point in time when the test signal TEST is output to a point in time when the test signal TEST is input and determine whether the semiconductor chip 100 has a defect, and thus, the quality and reliability of the semiconductor chip 100 and the semiconductor package 10 may be improved. In addition, by simultaneously inputting the test command signal TEST_CMD to the plurality of semiconductor chips 100 and determining whether the plurality of semiconductor chips 100 have defects, whether the plurality of semiconductor chips 100 have defects may be more quickly determined.

As is traditional in the field, the embodiments are described and illustrated in terms of blocks, as shown in the drawings including FIGS. 1, 2, 9 and 11 which carry out a described function or functions. These blocks, which may be referred to herein as units or modules or the like, or by names such as device, logic, circuit, counter, comparator, generator, converter, controller or the like, may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

While the embodiments have been particularly shown and described with reference to embodiments thereof, it will be understood that various changes in form and details may be made therein without departing from the spirit and scope of the following claims.

What is claimed is:

1. A semiconductor chip comprising:
a wiring structure arranged along an edge of the semiconductor chip;
a clock counter configured to output a test signal to a first node of the wiring structure and receive the test signal from a second node of the wiring structure; and
an oscillator configured to output a first clock signal to the clock counter,
wherein the clock counter is configured to count a number of clocks of the first clock signal as a first count value from a first time in which the test signal is output to the first node of the wiring structure to a second time in which the test signal is received from the second node of the wiring structure, and output a first resultant signal to a controller based on the first count value.

2. The semiconductor chip of claim 1, further comprising a clock generator configured to output a second clock signal to the clock counter,
wherein the clock counter is configured to generate the test signal based on the second clock signal.

3. The semiconductor chip of claim 1, wherein the clock counter is configured to output the test signal to the first node of the wiring structure in response to a test command signal received by the clock counter from the controller.

4. The semiconductor chip of claim 1, wherein the oscillator comprises a frequency control circuit for adjusting a frequency of the first clock signal.

5. The semiconductor chip of claim 1, wherein the clock counter is configured to output the first resultant signal having a first resultant value to the controller based on a determination the first count value is greater than or equal to a first reference value, and output the first resultant signal having a second resultant value to the controller based on a determination the first count value is less than the first reference value.

6. The semiconductor chip of claim 1, further comprising a sub clock counter configured to receive the test signal from a third node of the wiring structure and receive the first clock signal from the oscillator.

7. The semiconductor chip of claim 6, wherein the sub clock counter is configured to count a number of clocks of the first clock signal, as a second count value, from a third time in which the test signal is input to the first node of the wiring structure by the clock counter to a fourth time in which the test signal is received from the third node of the wiring structure, and output a second resultant signal to the controller based on the second count value.

8. The semiconductor chip of claim 7, wherein the sub clock counter is configured to output the second resultant signal having a first resultant value to the controller based on a determination the second count value is greater than or equal to a second reference value, and output the second resultant signal having a second resultant value to the controller based on a determination the second count value is less than the second reference value.

9. A semiconductor package comprising:
a semiconductor chip; and
a controller configured to output a test command signal to the semiconductor chip,
wherein the semiconductor chip comprises:
a wiring structure arranged in an edge of the semiconductor chip,
a clock counter configured to output a test signal to a first node of the wiring structure in response to the test command signal received from the controller and receive the test signal from a second node of the wiring structure, and
an oscillator configured to output a first clock signal to the clock counter, and
wherein the clock counter is configured to count a number of clocks of the first clock signal as a first count value from a first time in which the test signal is output to the first node of the wiring structure to a second time in which the test signal is received from the second node of the wiring structure, and output a first resultant signal to the controller based on the first count value.

10. The semiconductor package of claim 9, further comprising a clock generator configured to output a second clock signal to the clock counter,
wherein the clock counter is configured to generate the test signal based on the second clock signal.

11. The semiconductor package of claim 9, wherein the oscillator comprises a frequency control circuit for adjusting a frequency of the first clock signal.

12. The semiconductor package of claim 9, wherein the clock counter is configured to output the first resultant signal having a first resultant value to the controller based on a determination the first count value is greater than or equal to a first reference value, and output the first resultant signal having a second value to the controller based on a determination the first count value is less than the first reference value.

13. The semiconductor package of claim 12, wherein the controller is configured to read the first count value from the clock counter based on a determination the first resultant signal has the first resultant value.

14. The semiconductor package of claim 13, wherein the controller is configured to determine a defect level of the semiconductor chip based on the first count value.

15. The semiconductor package of claim 9, further comprising a sub clock counter configured to receive the test signal from a third node of the wiring structure and receive the first clock signal from the oscillator.

16. The semiconductor package of claim 15, wherein the sub clock counter is configured to count a number of clocks of the first clock signal, as a second count value, from a third time in which the test signal is input to the first node of the wiring structure by the clock counter to a fourth time in which the test signal is received from the third node of the wiring structure, and output a second resultant signal based on the second count value.

17. The semiconductor package of claim 16, wherein the sub clock counter configured to output the second resultant signal having a first resultant value based on a determination the second count value is greater than or equal to a second reference value, and output the second resultant signal having a second resultant value based on a determination the second count value is less than the second reference value.

18. The semiconductor package of claim 17, wherein the controller is configured to determine that a first area of the semiconductor chip has a defect based on a determination the first resultant signal has the first resultant value and the second resultant signal has the first resultant value, and determine that a second area of the semiconductor chip has a defect based on a determination the first resultant signal has the first resultant value and the second resultant signal has the second resultant value.

19. A semiconductor package comprising:
a plurality of semiconductor chips; and
a controller configured to output a test command signal to the plurality of semiconductor chips,
wherein each of the plurality of semiconductor chips comprises:
a wiring structure arranged in an edge of the semiconductor chip,
a clock counter configured to output a test signal to a first node of the wiring structure in response to the test command signal and receive the test signal from a second node of the wiring structure, and
an oscillator configured to output a first clock signal to the clock counter, and
wherein the clock counter is configured to count a number of clocks of the first clock signal as a first count value from a first time in which the test signal is output to the first node of the wiring structure to a second time in which the test signal is received from the second node of the wiring structure, and output a first resultant signal to the controller based on the first count value.

20. The semiconductor package of claim 19, wherein the controller is configured to simultaneously output the test command signal to the plurality of semiconductor chips.
